(19) United States
(12) Patent Application Publication
(10) Pub. No.: US 2009/0159868 A1
(43) Pub. Date: Jun. 25, 2009

(54) Phase change material layer and phase change memory device including the same

(75) Inventors: Youn-seon Kang, Seoul (KR); Tae-yon Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/153,559

(22) Filed: May 21, 2008

(30) Foreign Application Priority Data
Dec. 24, 2007 (KR) 10-2007-0136584

(51) Int. Cl. H01L 47/00

(52) U.S. Cl. 257/4; 257/E47.001

(57) ABSTRACT

Provided are a phase change material layer and a phase change random access memory (PRAM) device including the same. By providing a phase change material layer formed of a III-V family material and a chalcogenide, a PRAM device with a set time shorter than that of a conventional PRAM device and improved retention characteristics can be provided.

### CROSS-REFERENCE TO RELATED PATENT APPLICATION

This application claims the benefit of Korean Patent Application No. 10-2007-0136584, filed on Dec. 24, 2007, in the Korean Intellectual Property Office, the disclosure of which is incorporated herein in its entirety by reference.

### BACKGROUND OF THE INVENTION

1. Field of the Invention

The present invention relates to a phase change random access memory (PRAM) device, and more particularly, to a phase change material layer, having a short crystallization time and an excellent retention characteristic, and a PRAM device including the same.

2. Description of the Related Art

A phase change random access memory (PRAM) device is one of the next-generation memory devices, and is characterized by including a phase change material layer in a storage node to which data is stored.

A phase change material layer may be in either a crystalline state or an amorphous state such that both of the states can be reversibly changed. When a phase change material layer is in a crystalline state, the electrical resistance of the phase change material layer is lower than that of the phase change material layer in an amorphous state. A PRAM device is a memory device that records data by using a unique behavior of a phase change material of which the electrical resistance of the phase change material varies according to a state of the phase change material.

A PRAM device generally includes a phase change material layer and a switching structure connected to the same, where the switch structure may include a diode or a transistor. For example, a PRAM device includes a transistor formed on a silicon wafer, a bottom electrode contact layer connected to either a source or a drain of the transistor, and a phase change material layer. When an electrical pulse is applied to the phase change material layer, heat is generated at a region of the phase change material layer, and thus, the phase change material layer is in either a crystalline state or an amorphous state. Depending on the heat applied to the phase change material layer, its phase is changed to either a crystalline state or an amorphous state, and the electrical resistance of the phase change material layer is changed according to the states. Since electrical current or voltage is changed according to the electrical resistance of the phase change material layer, binary data can be written to and read from the phase change material layer.

A phase change material layer is generally formed of a GST(Ge₂Sb₂Te₅)-based material that is used in an optical recordable medium, such as a digital video disc (DVD) or a re-writable compact disc (CD-RW), and is referred to as a chalcogenide.

The operating speed of a PRAM device depends on time elapsed for a phase change between a crystalline state and an amorphous state. Although a material used for a conventional PRAM device is GST, the set time, which is generally the time required for the GST to store data, is more than 10 nanoseconds, and thus it is difficult to embody a PRAM device operating in a high speed.

### SUMMARY OF THE INVENTION

The present invention provides a phase change material layer requiring a shorter time to change its phase as compared to a conventional phase change material layer, and having an improved retention characteristic.

The present invention also provides a phase change random access memory (PRAM) device including the phase change material layer.

According to an aspect of the present invention, there is provided a phase change material layer including a III-V family material and a chalcogenide.

According to an embodiment of the present invention, the chalcogenide may be one from among oxygen (O), sulfur (S), selenium (Se), tellurium (Te), and polonium (Po), the III family material of the III-V family material may be one from among boron (B), aluminum (Al), indium (In), and gallium (Ga), and the V family material of the III-V family material may be either antimony (Sb) or bismuth (Bi).

According to an embodiment of the present invention, the phase change material layer may include TeₓIn_{y}Sb_{z} (x+y+z=1).

According to an embodiment of the present invention, the phase change material layer may include TeₓIn_{y}Sb_{z} (x+y+z=1), the atomic ratio x of Te may be 0≦x≦0.3, the atomic ratio y of In may be 0.3≦y≦0.6, and the atomic ratio z of Sb may be 0.3≦z≦0.6.

According to an embodiment of the present invention, the phase change material layer may include TeₓIn_{y}Sb_{z} (x+y+z=1), the atomic ratio x of Te may be 0.05≦x≦0.15, the atomic ratio y of In may be 0.45≦y≦0.55, and the atomic ratio z of Sb may be 0.45≦z≦0.55.

According to an embodiment of the present invention, the crystallizing temperature of the phase change material may be between 200° C. and 300° C.

According to another aspect of the present invention, there is provided a phase change random access memory (PRAM) device including a storage node, which includes a phase change material layer, and a switching device, which is connected to the storage node, wherein the storage node is formed of a III-V family material and a chalcogenide.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a phase change material layer according to an embodiment of the present invention;

FIG. 2 is a cross-sectional view of a PRAM device including a phase change material layer according to an embodiment of the present invention;

FIG. 3 is a cross-sectional view of a PRAM device including a phase change material layer according to an embodiment of the present invention;

FIGS. 4A and 4B are phase-temperature effect (PTE) diagrams of a phase change material layer according to an embodiment of the present invention;

FIG. 5 is a graph illustrating a switching characteristic of a PRAM device according to an embodiment of the present invention;

FIG. 6 is a graph illustrating X-ray diffraction (XRD) measuring results of a phase change material layer according to an embodiment of the present invention; and

FIG. 7 is a graph illustrating crystallizing temperatures of a phase change material layer according to an embodiment of the present invention.

### DETAILED DESCRIPTION OF THE INVENTION

A phase change material layer and a phase change random access memory (PRAM) device including the same according to an embodiment of the present invention will now be described more fully with reference to the accompanying drawings. In the drawings, the thicknesses of layers and regions are exaggerated for clarity. The phase changing temperature of the phase change material layer is between 200° C. and 300° C. Since a crystallization time of the phase change material layer is short, the set time and retention characteristics of the PRAM device can be improved.

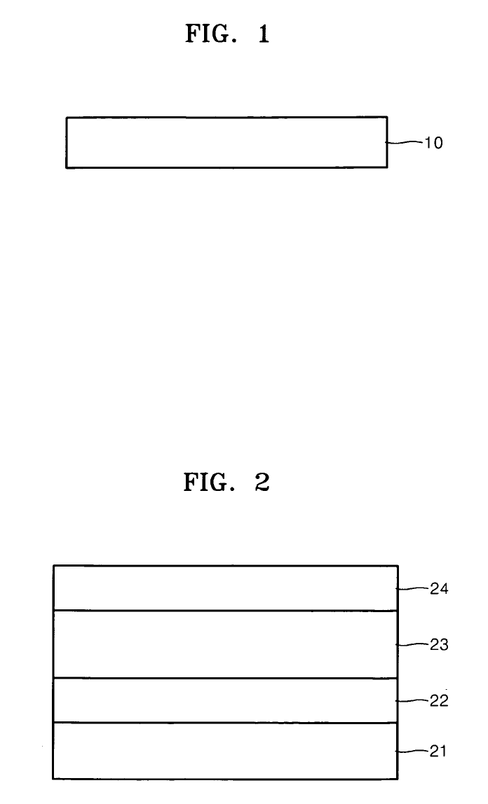

FIG. 1 is a cross-sectional view of a phase change material layer according to an embodiment of the present invention. The phase change material layer is formed of a III-V alloy and a chalcogenide. The chalcogenide may be oxygen (O), sulfur (S), selenium (Se), tellurium (Te), or polonium (Po). A III family material of the III-V alloy may be boron (B), aluminum (Al), indium (In), or gallium (Ga). A V family material of the III-V alloy may be a antimony (Sb) or bismuth (Bi). More particularly, a TeₓIn_{y}Sb_{z} (x+y+z=1) may be used, wherein Te is used as the chalcogenide, In as the III family material, and Sb as the V family material. The atomic ratio x of Te in TeₓIn_{y}Sb_{z} is 0≦x≦0.3, and may be 00.5≦x≦0.15. The atomic ratio y of In in TeₓIn_{y}Sb_{z} is 0.3≦y≦0.6, and may be 0.45≦y≦0.55. The atomic ratio z of Sb TeₓIn_{y}Sb_{z} is 0.3≦z≦0.6, and may be 0.45≦z≦0.55.

The phase change material layer according to an embodiment of the present invention may be formed by using a method such as a chemical vapor deposition (CVD), a physical vapor deposition (PVD), or an atomic layer deposition (ALD). Hereinafter, a method of fabricating a phase change material layer according to an embodiment of the present invention will be described. If a sputtering method is used to form the phase change material layer, the phase change material layer may be formed by using a compound target including both a chalcogenide and a III-V family material. Also, a co-sputtering method may be used either by using a III-V family alloy target and a chalcogenide target or a III family material, a V family material, and a chalcogenide as separate targets.

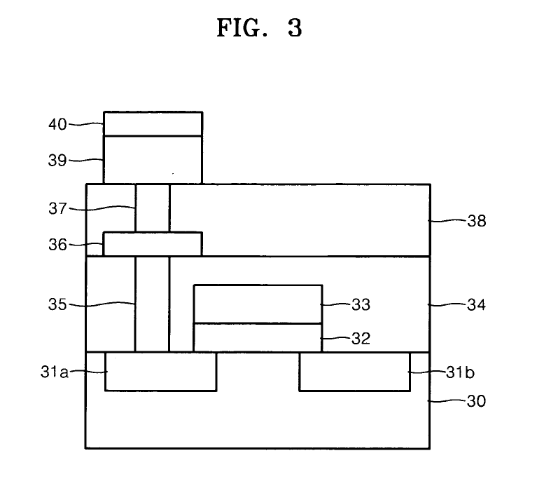

FIG. 2 is a cross-sectional view of a PRAM device including a phase change material layer according to an embodiment of the present invention. Referring to FIG. 2, a bottom electrode 22 is formed above a switch structure 21, and a phase change material 23 and a top electrode 24 are sequentially formed on the bottom electrode 22. The switch structure 21 may be formed by using a diode or a transistor.

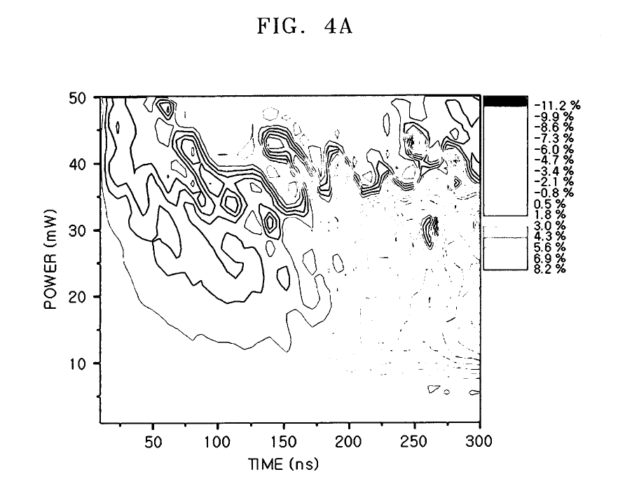

FIG. 3 is a sectional view of a PRAM device including a phase change material layer 39 according to an embodiment of the present invention.

Referring to FIG. 3, a first impurities region 31a and a second impurities region 31b are formed in a semiconductor substrate 30, and a gate insulation layer 32 and a gate electrode 33 are formed on the semiconductor substrate 30 to cover the first and the second impurities regions 31a and 31b. Thus, the semiconductor substrate 30, the first and the second impurities regions 31a and 31b, and the gate electrode 33 form a electric field effect transistor (hereinafter referred to as ‘transistor T’). A contact hole (now shown) is formed in a first interlayer insulation layer 34 that is formed on the semiconductor substrate 30 to also cover the gate electrode 33 and the gate insulation layer 32 so as to expose the first impurities region 31a and then form a conductive plug 35 therein. Although not shown, the conductive plug 35 may be formed on the second impurities region 31b. A bottom electrode 36 and a bottom electrode contact layer 37 are formed on the conductive plug 35. The bottom electrode 36 may be formed of TiN or TiAIN, and the bottom electrode contact layer 37 may be formed of the same material. A second interlayer insulation layer 38 is formed on the first interlayer insulation layer 34, and the phase change material layer 39 and a top electrode 40 are sequentially formed on the bottom electrode contact layer 37.

While the bottom electrode 36, the bottom electrode contact layer 37, the phase change material layer 39, and the top electrode 40 form a storage node of the PRAM device, the shape of the storage node may vary as the one shown. The phase change material layer 39 is formed by a III-V alloy and a chalcogenide. As described above, the chalcogenide may be O, S, Se, Te, or Po, a III family material of the III-V alloy may be B, Al, In, or Ga, and a V family material of the III-V alloy may be Sb or Bi.

The operation of the PRAM device according to the current embodiment will be described below. While a transistor is on, an operating voltage is applied between the second impurities region 31b and the top electrode 40, where the operating voltage refers to a writing voltage for writing data to the phase change material layer 39. Due to the writing voltage, a reset current is applied to the phase change material layer 39, so that the phase change material layer 39 is in an amorphous state, representing that binary data such as “0” or “1” is written to the phase change material layer 39. For example, if the phase change material layer 39 is in an amorphous state, it is determined that data “1” is written to the phase change material layer 39.

A case in which the operation voltage is a reading voltage to read data written to the phase change material layer 39 will be described below. When the operating voltage is the reading voltage, the electrical resistance of the phase change material layer 39 may be measured to be compared with a reference electrical resistance. Thus, if the measured electrical resistance of the phase material layer 39 is lower than the reference electrical resistance, it is determined that data “0” is read from the phase change material layer 39. In contrast, if the measured electrical resistance of the phase material layer 39 is higher than the reference electrical resistance, it is determined that data “1” is read from the phase change material layer 39. Data written and read to/from the phase change material layer 39 based on the comparison between the measured electrical resistance and the reference electrical resistance may be oppositely assigned according to an embodiment of the present invention.

If the operating voltage is an erasing voltage to erase data written to the phase change material layer 39, a set current is applied to the phase change material layer 39. As a result, an amorphous region of the phase change material layer 39 becomes a crystalline region.

Hereinafter, a phase change material layer and characteristics of a PRAM device including the same according to an embodiment of the present invention will now be described more fully with reference to the accompanying drawings.

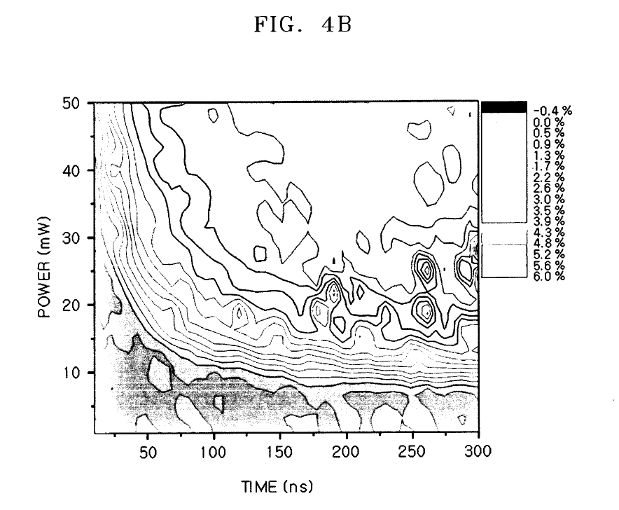

FIGS. 4A and 4B are phase-temperature effect (PTE) diagrams of phase change material layers according to an embodiment of the present invention. The diagram shows that the phases of the phase change material layers changed due to irradiation of a 650-nm laser, wherein a horizontal axis represents time and a vertical axis represents applied electrical current. FIG. 4A is regarding a phase change material layer having an atomic structure of Te_{0.1}In_{0.48}Sb_{0.41}, while FIG. 4B is regarding a phase change material layer having an atomic structure of Te_{0.71}In_{0.44}Sb_{0.39}.

Referring to FIGS. 4A and 4B, it is clear that in both of the phase change material layers, a dramatic phase change occurs around 50 mW, which is the operating region of general PRAM devices, in a very short time of less than 10 ns. For a general GST(Ge₂Sb₂Te₅) phase change material layer, it takes approximately 150 ns to be completely crystallized. In contrast, the phase change material layers according to embodiments of the present invention require a shorter time to change phase as compared to that of a general PRAM device, and thus a set time may be significantly improved when a PRAM device including a phase change material layer according to an embodiment of the present invention is operated.

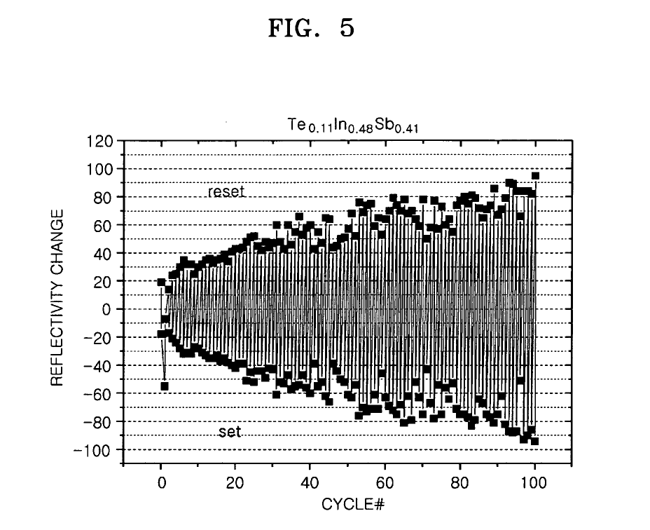

FIG. 5 is a graph illustrating a switching characteristic of a PRAM device according to an embodiment of the present invention. A phase change material layer used in the PRAM device has an atomic structure of Te_{0.11}In_{0.48}Sb_{0.41}. In FIG. 5, a horizontal axis represents the number of sets and resets, while a vertical axis represents reflexivity. In other words, a region with high reflexivity represents a crystalline state, while a region with low reflexivity represents an amorphous state.

Referring to FIG. 5, when set and reset are repeated, the differences in a crystalline state and an amorphous state are clearly distinguishable, and thus the PRAM device can be used efficiently as a memory device.

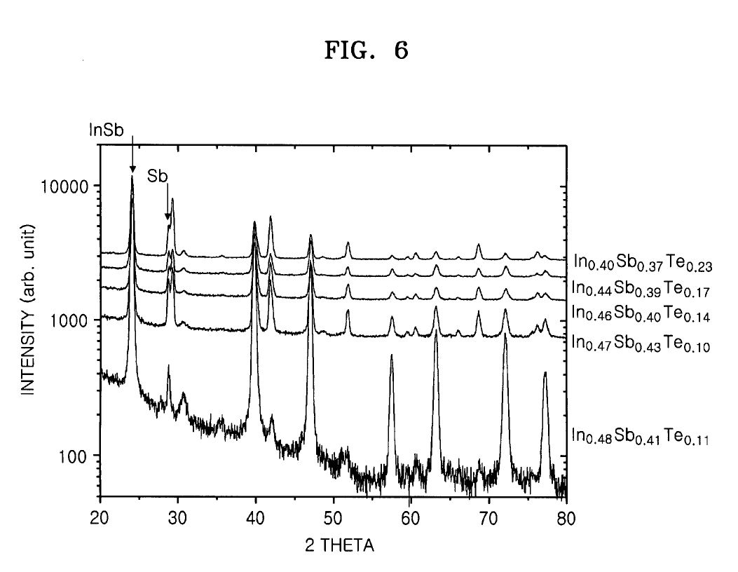

FIG. 6 is a graph illustrating X-ray diffraction (XRD) measuring results of a phase change material layer according to an embodiment of the present invention. Referring to FIG. 6, when a PRAM device is basically formed of InSb including Te, the PRAM device has a cubic single phase for its crystal structure and thus making the PRAM device advantageous in terms of switching. However, a multi-phase results as the atomic ratio of Te increases.

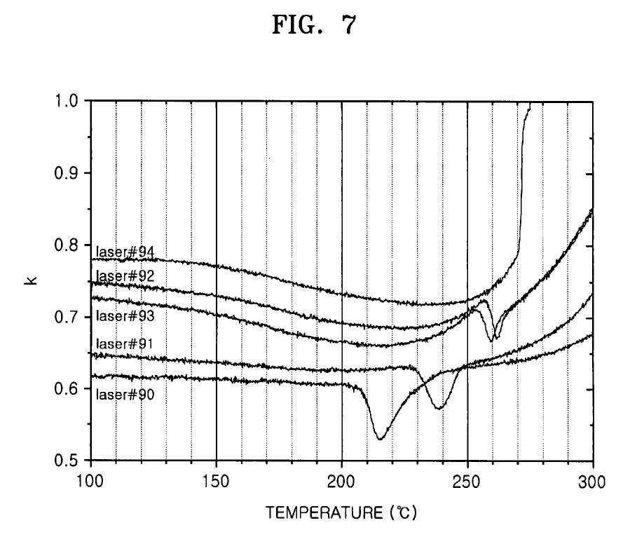

FIG. 7 is a graph illustrating crystallizing temperatures of phase change material layers according to an embodiment of the present invention. In FIG. 7, a horizontal axis represents temperature, while a vertical axis represents an extinction coefficient k of the phase change material layers, where the extinction coefficient k is an optical coefficient. More specifically, the graph is obtained by observing change of extinction rate of the phase change material layer due to change of phase between a crystalline state and an amorphous state caused by change of temperature. Referring to FIG. 7, lasers #90 through #94 are respectively irradiated onto In_{0.48}Sb_{0.41}Te_{0.11}, In_{0.47}Sb_{0.43}Te_{0.10}, In_{0.44}Sb_{0.39}Te_{0.17}, In_{0.46}Sb_{0.40}Te_{0.14}, and In_{0.40}Sb_{0.37}Te_{0.23}.

Referring to FIG. 7, it is clear that the extinction coefficients k of the phase change material layers having the aforementioned five atomic structures change dramatically at temperatures between 200° C. and 300° C. Therefore, a crystallizing temperature of a phase change material layer according to an embodiment of the present invention is between 200° C. and 300° C.

As described above, a phase change material layer according to an embodiment of the present invention requires a very short time for crystallization, and thus a set time can be significantly improved. Moreover, since a crystallizing temperature of the phase change material layer is fairly high, and thus, the retention characteristic of a PRAM device including the phase change material layer is improved.

While this invention has been particularly shown and described with reference to preferred embodiments thereof, it will be understood by one skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A phase change material layer comprising a III-V family material and a chalcogenide.

2. The phase change material layer of claim 1, wherein the chalcogenide is one from among O (oxygen), S (sulfur), Se (selenium), Te (tellurium), and Po (polonium).

3. The phase change material layer of claim 1, wherein the III family material of the III-V family material is one from among B (boron), Al (aluminum), In (indium), and Ga (gallium).

4. The phase change material layer of claim 1, wherein a V family material of the III-V family material is either Sb (antimony) or Bi (bismuth).

5. The phase change material layer of claim 1, wherein the phase change material layer comprises TeₓIn_{y}Sb_{z} (x+y+z=1).

6. The phase change material layer of claim 5, wherein the phase change material layer comprises TeₓIn_{y}Sb_{z} (x+y+z=1), the atomic ratio x of Te in TeₓIn_{y}Sb_{z} is 0≦x≦0.3, the atomic ratio y of In in TeₓIn_{y}Sb_{z} is 0.3≦y≦0.6, and the atomic ratio z of Sb in TeₓIn_{y}Sb_{z} is 0.3≦z≦0.6.

7. The phase change material layer of claim 5, wherein the phase change material layer comprises TeₓIn_{y}Sb_{z} (x+y+z=1), the atomic ratio x of Te in TexInySbz is 0.05<x≦50.15, the atomic ratio y of In in TeₓIn_{y}Sb_{z} is 0.45≦y≦50.55, and the atomic ratio z of Sb in TeₓIn_{y}Sb_{z} is 0.45≦z≦50.55.

8. The phase change material layer of claim 1, wherein the crystallizing temperature of the phase change material is between 200° C. and 300° C.

9. A phase change random access memory (PRAM) device comprising:
a storage node comprising a phase change material layer; and
a switching device connected to the storage node,
wherein the storage node is formed of a III-V family material and a chalcogenide.

10. The PRAM device of claim 9, wherein the chalcogenide is one from among 0, S, Se, Te, and Po.

11. The PRAM device of claim 9, wherein a III family material of the III-V family material is one from among B, Al, In, and Ga.

12. The PRAM device of claim 9, wherein a V family material of the III-V family material is either Sb or Bi.

13. The PRAM device of claim 9, wherein the phase change material layer comprises TeₓIn_{y}Sb_{z} (x+y+z=1).

14. The PRAM device of claim 9, wherein the phase change material layer comprises TeₓIn_{y}Sb_{z} (x+y+z=1), the atomic ratio x of Te in TeₓIn_{y}Sb_{z} is 0<x≦50.3, the atomic ratio y of In in TeₓIn_{y}Sb_{z} is 0.3≦y≦50.6, and the atomic ratio z of Sb in TeₓIn_{y}Sb_{z} is 0.3≦z≦0.6.

15. The PRAM device of claim 9, wherein the phase change material layer comprises TeₓIn_{y}Sb_{z} (x+y+z=1), the atomic ratio x of Te in TeₓIn_{y}Sb_{z} is 0.05≦x≦0.15, the atomic ratio y of In in TeₓIn_{y}Sb_{z} is 0.45≦y≦0.55, and the atomic ratio z of Sb in TeₓIn_{y}Sb_{z} is 0.45≦z≦0.55.

16. The PRAM device of claim 9, wherein a crystallizing temperature of the phase change material is between 200° C. and 300° C.
